(19) United States
(12) Patent Application Publication
(10) Pub. No.: US 2026/0144150 A1
(43) Pub. Date: May 21, 2026

(54) METHOD OF MANUFACTURING OF AN ELECTRONIC DEVICE

(71) Applicant: STMicroelectronics International N.V., Geneva (CH)

(72) Inventors: Romain COFFY, Voiron (FR); Julien CUZZOCREA, Montbonnot St Martin (FR)

(73) Assignee: STMicroelectronics International N.V., Geneva (CH)

(21) Appl. No.: 19/387,881

(22) Filed: Nov. 13, 2025

(30) Foreign Application Priority Data
Nov. 15, 2024 (FR) FR2412476

(51) Int. Cl. H01L 23/00; H01L 25/065

(52) U.S. Cl. CPC H10W 90/00; H10W 70/09; H10W 70/093; H10W 70/60; H10W 70/6528; H10W 90/792

(57) ABSTRACT

An organic film is laminated onto an assembly which includes a substrate having a first chip formed therein and conductive pads positioned thereon, and a second chip mounted on the substrate and connected to the first chip. The second chip includes through vias. Openings are formed in the organic film opposite the conductive pads and the through vias. Contacting areas are formed on the organic film, all the way to the conductive pads and to the through vias. An electrically-insulating element is placed on the organic film and openings are formed in the electrically-insulating element opposite the contacting areas. Conductive elements are then formed on the contacting areas.

### PRIORITY CLAIM

This application claims the priority benefit of French Application for Patent No. FR2412476, filed on November 15, 2024, the content of which is hereby incorporated by reference in its entirety to the maximum extent allowable by law.

### TECHNICAL FIELD

The present disclosure generally concerns the field of electronic devices and, more particularly, electronic devices comprising chips assembled by direct bonding to substrates (referred to as “Die to Wafer”) and the integration of chips on external devices by a so-called flip-chip transfer technique.

### BACKGROUND

In a heterogeneous integration of Die-to-Wafer (D2W) type, the active surface of an upper chip is assembled by hybrid bonding to the active surface of a lower chip formed in a substrate. When it is necessary to have connections directly on the two chips (for example, to have a power/distribution network without incurring an ohmic drop), through silicon vias (TSVs) are formed in the upper chip. Interconnection elements (pillars or bumps) are then formed. Part of the interconnection elements are formed on the TSVs and thus connected to the upper chip via the TSVs, and another part of the interconnection elements are formed on connection areas positioned on the substrate and connected to the lower chip. The electronic component thus obtained can then be assembled to an external element, such as a printed circuit board.

However, even with very thin upper chips (typically having a thickness in the range from 20 to 30 µm), the height difference between the base of the different interconnection elements is non-negligible. The interconnection elements formed then exhibit a non-coplanarity. The mounting of the electronic component on a printed circuit board is then impossible and/or may cause thermomechanical stress within the final device, thus decreasing its reliability over time.

There exists a need to have electronic components comprising a substrate having a chip formed therein and having another chip mounted thereon, for example by means of a die-to-wafer (D2W) bonding process, the electronic components needing to be able to be easily assembled to external elements, typically printed circuit boards, by a so-called flip chip transfer technique in a durable and reliable manner.

### SUMMARY

In an embodiment, a a method of manufacturing an electronic device comprises the following steps: a) providing an assembly comprising a substrate having a first chip formed therein and having conductive pads positioned thereon, and a second chip mounted on a first surface of the substrate, wherein a first surface of the second chip is arranged opposite the first chip and connected to the first chip, and wherein the second chip comprises through vias emerging onto a second surface of the second chip; b) laminating a first organic film onto the first surface of the substrate and onto the second chip; c) forming openings in the first organic film opposite the conductive pads and the through vias, so as to make them accessible; d) forming contacting areas through the openings from an upper surface of the first organic film, on the on hand, all the way to the conductive areas and, on the other hand, all the way to the through vias; e) depositing an electrically-insulating element (for example, by laminating a second organic film or by depositing a passivation layer) on the first organic film and on the contacting areas; f) forming openings in the electrically-insulating element so as to make the contacting areas accessible; and g) forming conductive elements on the contacting areas.

According to a specific embodiment, the conductive elements are electrically-conductive pillars or solder balls.

According to a specific embodiment, the openings formed in the first organic film and/or the openings formed in the electrically-insulating element are made by laser ablation.

According to a specific embodiment, the conductive elements are formed opposite the through vias.

According to a specific embodiment, the contacting areas of the conductive areas are continued on the upper surface of the first organic film, whereby the conductive elements are offset with respect to the conductive areas.

According to a specific embodiment, the method comprises, prior to step d), a step of forming an electrically-insulating material a second surface of the substrate and on lateral surfaces of the substrate.

In an embodiment, an electronic device comprises: a substrate having a first chip formed therein and having conductive pads positioned thereon; a second chip mounted on a first surface of the substrate; wherein a first surface of the second chip is arranged opposite the first chip and connected to the first chip; wherein the second chip comprises through vias emerging onto a second surface of the second chip; a first organic film laminated onto the first surface of the substrate and onto the second chip; wherein openings in the first organic film are opposite the conductive areas and the through vias; contacting areas extending from an upper surface of the first organic film, on one hand, all the way to the conductive areas and, on another hand, all the way to the through vias, the contacting areas of the conductive areas continuing on an upper surface of the first organic film; an electrically-insulating element covering the first organic film (the electrically-insulating element comprising, for example, a second laminated organic film or a passivation layer) and having openings so as to make the contacting areas accessible; and conductive elements (for example, solder balls or conductive pillars) on the contacting areas.

According to a specific embodiment, an electrically-insulating material is formed on a second surface and on lateral surfaces of the substrate.

In an embodiment, an assembly comprises: a device such as previously defined, and a printed circuit board comprising connection areas, the conductive elements being assembled on the connection areas.

In an embodiment, a method of manufacturing an assembly, such as previously defined, comprises a step during which the conductive elements are assembled on the connection areas of the printed circuit board (for example, during a soldering step).

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1F schematically show steps of a method of manufacturing a D2W-type electronic component;

FIGS. 2A to 2F schematically show steps of a second part of a method of manufacturing a D2W-type electronic component;

FIG. 3 and FIG. 4 are simplified cross-section views of various assemblies comprising an electronic component and a printed circuit board, according to different specific embodiments; and

FIG. 5 is an image obtained with an optical microscope of a device comprising a substrate having a 20-µm deep hole, onto which an organic film has been laminated, openings then being formed in the laminated organic film, a metal layer being deposited on the laminated organic film and in the openings.

### DETAILED DESCRIPTION

The various elements in the drawings are not necessarily shown at a uniform scale to make them easier to read.

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings in a normal position of use.

Unless specified otherwise, the expressions "about", "approximately", "substantially", and "in the order of" signify plus or minus 10%, preferably of plus or minus 5%.

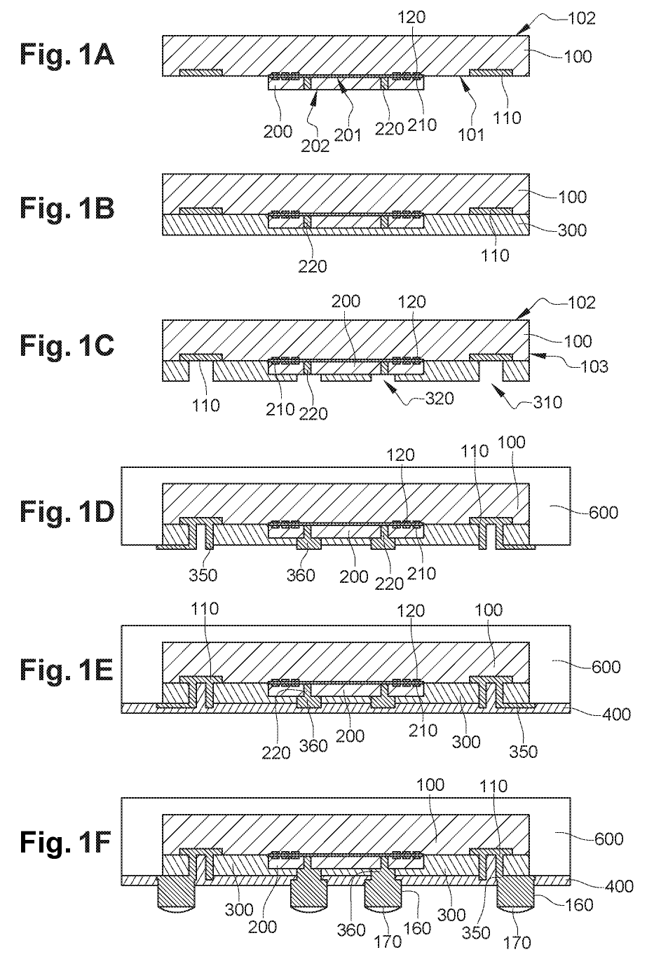

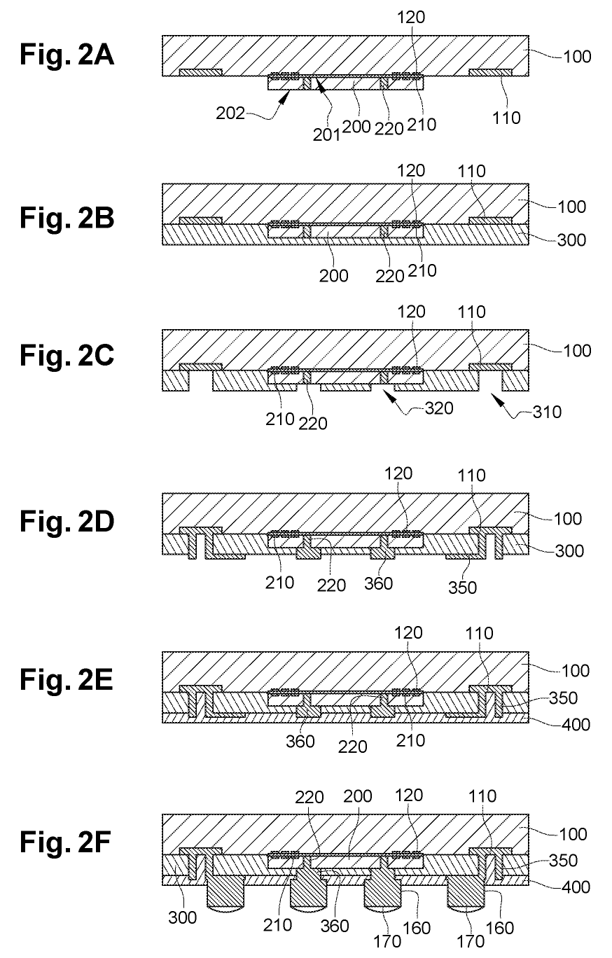

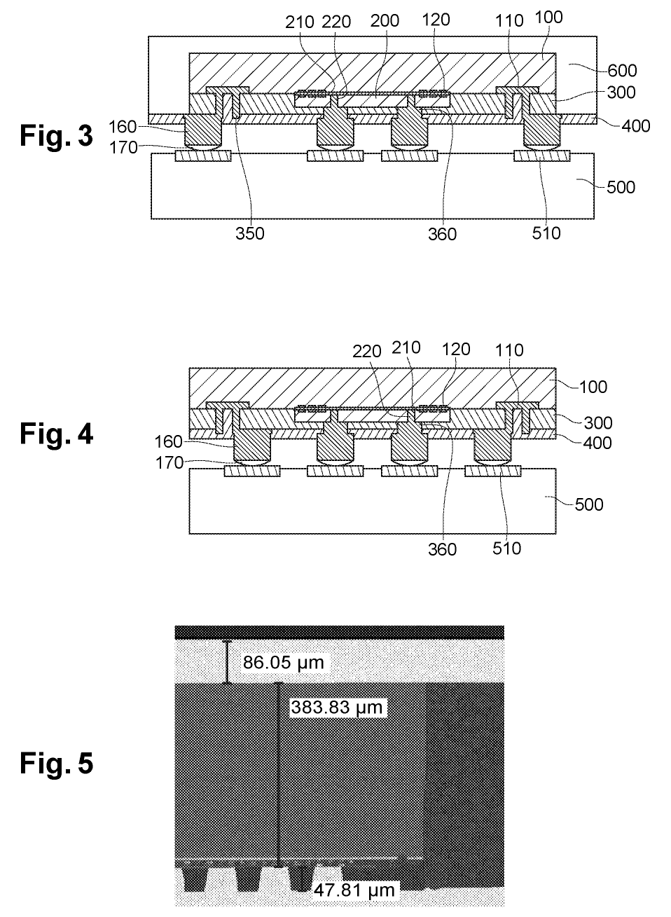

The electronic component manufacturing method will now be described in detail, with reference to FIGS. 1 to 1F as well as to FIGS. 2A to 2F.

The method comprises the following steps:

FIGS. 1A, 2A: step a) providing an assembly comprising a substrate 100 having a first chip formed therein and having conductive pads 110 positioned thereon, a second chip 200 being mounted on a first surface 101 of substrate 100, a first surface 201 of second chip 200 being arranged opposite the first chip and connected to the first chip, second chip 200 comprising vias 220 emerging onto a second surface 202 of the second chip 200 and forming conductive contacts.

FIGS. 1B, 2B: step b) laminating a first organic film 300 onto the assembly provided at step a) so as to cover substrate 100 and second chip 200.

FIGS. 1C, 2C: step c) forming openings 310, 320 in the first organic film 300 opposite conductive pads 110 and through vias 220, so as to make them accessible.

FIGS. 1D, 2D: step d) forming contacting areas 350, 360 from an upper surface of the first organic film 300, on the one hand, all the way to conductive areas 110 and, on the other hand, all the way to through vias 220.

FIGS. 1E, 2E: step e) depositing an electrically-insulating element 400 on the first organic film 300 and on contacting areas 350, 360, for example by laminating a second organic film or by depositing a passivation layer, for example a resin layer.

Step f) forming openings in electrically-insulating element 400 to provide access to contacting areas 350, 360.

FIGS. 1F, 2F: step g) forming conductive elements 160 on contacting areas 350, 360, whereby interconnects for the first chip and interconnects for the second chip 200 are obtained.

Thus, the interconnects of the electronic components are formed in two steps: in a first step, contacting areas 350, 360 (forming the lower portion 350, 360 of the interconnects of the first chip and of the second chip) are formed in the openings 310, 320 of laminated organic film 300; and in a second step, conductive elements 160 (forming the upper portion 160 of the interconnects of the first chip and of the second chip 200) are formed simultaneously, conductive elements 160 having the same height.

The resulting interconnects are coplanar. During the method, no thinning step is required. With such a method, it is possible to achieve a very fine pitch (for example in the order of 100 µm).

The assembly provided at step a) comprises substrate 100 having the first chip (or lower chip) and the second chip 200 (or upper chip) formed therein (FIG. 1A, 2A). The first chip and the second chip are arranged opposite each other and connected to each other by connection areas 120, 210.

Substrate 100 comprises a first surface 101 and a second surface 102, as well as lateral surfaces 103. The connection areas 120 of the first chip are positioned on the first surface of substrate 100. Connection areas 110, connected to the first chip, are also positioned on the first surface 101 of substrate 100. Connection areas 110 are positioned around the first chip and are used to connect the first chip to an external element.

Second chip 200 comprises a first surface 201 (front side) and a second surface 202 (back side).

The first surface 201 of second chip 200 is arranged opposite the first chip and connected to the first chip using connection areas 210 positioned on the first surface 201 of second chip 200.

Second chip 200 comprises through silicon vias (TSVs) 220. Vias 220 run from the first surface 201 of second chip 200 to the second surface 202 of chip 200. Through silicon vias 220 emerge onto the second surface 202 of second chip 200 and form conductive contacts used to connect the second chip to an external element.

Second chip 200 has a thickness, for example, smaller than 60 µm, for example smaller than or equal to 30 µm (for example in the range from 20 to 30 µm) or smaller than 10 µm (for example in the range from 6 to 10 µm).

Preferably, a plurality of first chips are formed in substrate 100 (for example, provided by a semiconductor wafer) and a plurality of second chips 200 are assembled to the plurality of first chips. This is an assembly of D2W (die-to-wafer) type achieved by hybrid bonding. The pads 120 of the first chips are bonded to the pads 210 of the second chips 200. A low chip-to-chip impedance is obtained. The method comprises a step, after step e), during which substrate 100 is cut (i.e., diced or singulated as referred in the art) to separate the chips.

During step b), a first organic film 300 is laminated onto the first surface 101 of substrate 100 and onto first chip 200. The first organic film 300 is, for example, a film marketed by Ajinomoto® as Ajinomoto Build-up Film (ABF). A first surface (or lower surface) of the laminated film is in contact with the substrate and with the first chip. A second surface (or upper surface) of film 300 is free at this stage of the method. Such a film can absorb high topologies, and in particular the thickness of the second chip.

The thickness of first organic laminate 300 is greater than the thickness of second chip 200.

During step c), openings 310, 320 are formed across the thickness of the first laminated film 300, from its upper surface facing through holes 220 and conductive pads 110, so as to make them accessible (FIGS. 1C, 2C). Openings 310, 320 are through holes. First openings 310 are positioned in line with the conductive pads 110 of substrate 100 and second openings 320 are positioned in lines with the vias 220 of second chip 200. This step is carried out, for example, by means of a laser.

Preferably, the surface area of the first openings 310 is smaller than the surface area of conductive pads 110. Preferably, the surface area of the second openings 320 is greater than the surface area of vias 220.

Between step c) and step d), the method may further comprise a step during which an electrically-insulating material 600 is formed on the back side 102 of substrate 100 and/or on the flanks 103 of substrate 100 to form a protective package (FIG. 1D). Electrically-insulating material 600 is, for example, an electrically-insulating resin. Insulating material 600 is, for example, selected from among epoxy-type resins, phenolic-type resins, acrylic-type resins.

Preferably, the resin is a thermosetting or photosensitive (UV) resin. Such resins are highly stable and resistant to many chemicals.

The resin polymerization is, for example, a UV polymerization step. It may also be carried out by heating or any other polymerization operation that will be selected according to the nature of the material used. An anneal step may be carried out after the polymerization step.

Preferably, a plurality of substrates are simultaneously embedded in the resin to form a panel-type device.

During step d), contacting areas 350, 360 are formed through the openings 310, 320 of the first laminated organic film 300.

Contacts 350, 360 are, for example, made of metal or of a metal alloy. They are, for example, made of copper.

A seed layer, not shown, may cover conductive pads 110 and vias 220. The seed layer enables to grow contacting areas 350, 360 by electrodeposition. The seed layer is, for example, made of TiCu.

First contacting areas 350 form continuous conductive lines from conductive pads 110 to the second side of the first laminated organic film 300. First contacting areas 350 may be continued on the second surface of the first laminated film 300 to form offset contacting areas. A redistribution layer (RDL) is thus formed, enabling to position conductive elements 160 in offset fashion with respect to connection areas 110 for a better interconnection with external components 500. Offset contacting areas 350 are particularly advantageous in the case of the manufacturing of a panel.

Second contacting areas 360 form continuous conductive lines from through vias 220 to the second surface of the first laminated organic film 300.

Contacting areas 350, 360 may completely or partially fill openings 310, 320. For example, the first openings 310 are partially filled and the second openings 320 are completely filled.

During step e), an electrically-insulating element 400 is formed on the first laminated organic film 300 and on contacting areas 350, 360. Preferably, electrically-insulating element 400 is organic.

According to a first alternative embodiment, electrically-insulating element 400 is a second laminated organic film.

According to a second alternative embodiment, electrically-insulating element 400 is a passivation layer. Passivation layer 420 is, for example, an oxide layer, a resin layer, or a polymer layer, preferably made of polyimide (PI) or of polybenzoxazole (PBO).

Electrically-insulating element 400 acts as a buffer layer and absorbs part of the mechanical stress applied to conductive pillars 160.

During step f), openings are formed in electrically-insulating element 400 to make the contacting areas (first contacting areas 350 and second contacting areas 360) accessible.

During step g), conductive elements 160 are formed on contacting areas 350, 360.

Conductive elements 160 are formed simultaneously on the contacting areas 350 of connection areas 110 and on the contacting areas 360 of vias 220 with the same manufacturing parameters.

Conductive elements 160 are coplanar.

At least a portion (the periphery) of conductive elements 160 covers electrically-insulating element 400, which improves the resistance of the resulting device to mechanical stress.

Depending on the position of the contacting areas, conductive elements 160 may be arranged opposite the contacting areas 350 of conductive areas 110 or offset with respect to the contacting areas 350 of conductive areas 110.

Step g) may be carried out according to two alternative embodiments.

According to a first alternative embodiment shown, for example, in the appended drawings, conductive elements 160 are pillars.

Conductive elements 160 in the form of pillars are, for example, made of copper.

Conductive elements 160 are preferably covered by a solder layer 170.

Solder layer 170 may be made of a tin-based alloy, for example, an SnAgCu alloy.

According to this alternative embodiment, step g) may be carried out according to the following sub-steps: depositing a primer layer, preferably over the entire wafer; forming a resin having openings opposite contacting areas 350, 360; forming conductive elements 160 on contacting areas 350, 360, then depositing a solder layer 170; removing the resin and the portion of the primer layer not covered by conductive elements 160; and preferably performing a reflow to melt solder layer 170 and form solder pads on connection elements 160.

According to a second alternative embodiment, not shown, conductive elements 160 are solder balls. They may be deposited through a mask or by an automatic ball placement tool. They are deposited on contacting areas 350, 360.

The solder balls may be made of a tin-based alloy, for example an SnAgCu alloy.

The method may be a panel level packaging (PLP) method (FIGS. 1A to 1F).

The method may be a wafer level chip scale package (WLCSP) method (FIGS. 2A to 2F).

For a WLCSP-type method, as previously indicated, after the implementation of steps a) to g), a cutting step, during which the chips are separated, may be carried out.

In the case of a device of inner routing type (referred to as “FanIn”), the cutting step for separating the chips is implemented at the end of the method, that is, after having formed the interconnects. The manufacturing of this device does not require depositing a layer of electrically-insulating material on the back side and on the lateral surfaces of the substrate.

In the case of a device of inner and outer routing (referred to as “FanOut”) type, the cutting step for separating the chips is implemented before forming the interconnects. More particularly, the steps are carried out in the following order: cutting substrate 100 to separate the chips; depositing the layer of electrically-insulating material so as to cover the back side 102 and the lateral surfaces 103 of the chip substrate; and forming the interconnects.

The resulting electronic device comprises (FIG. 1F and FIG. 2F): a first group of interconnects formed on substrate 100 and connected to the first connection areas 110, and a second group of interconnects formed on the second surface 202 of second chip 200 and connected to vias 220.

The first group of interconnects enables to connect the chip of substrate 100 to external element 500, and the second group of interconnects enables to connect second chip 200 to external element 500.

The interconnects of the first group of interconnects comprise: a first portion (or lower portion) formed of contacting area 350 running through the first openings 310 of laminated film 300, and a second portion (or upper portion) formed of conductive element 160, and optionally of a solder pad 170.

The interconnects of the second group of interconnects comprise: a first portion (or lower portion) formed of contacting area 360 running through the second openings 320 of laminated film 300, and a second portion (or upper portion) formed of conductive element 160, and optionally of a solder pad 170.

The mechanical stress on the interconnects is decreased thanks to the presence of laminated film 300 and of electrically-insulating element 400.

The upper surfaces of conductive elements 160 are at the same distance from the first surface 101 of substrate 100, which facilitates the positioning and the assembly of the interconnects with an external element 500, such as a printed circuit board (PCB) or a laminated substrate (FIGS. 4 and 5).

Since the interconnects are coplanar, the electronic device can be assembled by any conventional technique, for example by a bumping technique.

In particular, the method of assembly of the device to an external element 500 comprises a step during which the interconnects are aligned and brought into contact with the connection areas 510 of device 500, and a step, for example of soldering, during which the interconnects are bonded to connection areas 510. The soldering ensures the electrical and mechanical contact between the device and the external element. It can be achieved either by adding additional solder paste, or with a soldering flux which deoxidizes and holds the device during the step of reflow of solder balls 160 or solder pads 170 on connection areas 510.

The electronic device may be an analog memory device. It can be used in systems requiring a high number of inputs/outputs (I/O). It is particularly advantageous for the automotive field (especially for a microcontroller unit (MCU)) or for personal (for example, consumer) objects.

### Illustrative and non-limiting example

As an illustration, a substrate in which a chip is formed has been used. A 30 µm-wide trench has been cut by laser. It is positioned on the edge of the chip. An ABF film has been laminated onto the substrate. The ABF film completely fills the trench. Holes have then been formed in the ABF film and filled with metal to form contacting areas. FIG. 5 shows the resulting device.

In an implementation, the upper surface of the first film is covered by the electrically insulating element 400 and that the lower surface of the first film covers the first surface 101 of the substrate 100 and the first chip 200. In other words, on the side of the upper surface of the first film, there is the electrically insulating element 400 and, on the side of the lower surface of the first film, there is the substrate 100 and first chip 200.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an electronic device, comprising the following steps:
a) providing an assembly comprising: a substrate having a first chip formed therein and having conductive pads positioned thereon, and a second chip mounted on a first surface of the substrate, wherein a first surface of the second chip is arranged opposite the first chip and connected to the first chip, and wherein the second chip comprises through vias emerging onto a second face of the second chip;
b) laminating a first organic film onto the first surface of the substrate and onto the second chip;
c) forming openings in the first organic film opposite the conductive areas and the through vias, so as to make them accessible;
d) forming contacting areas through the openings from an upper surface of the first organic film, on one hand, all the way to the conductive pads and, on another hand, all the way to the through vias;
e) depositing an electrically-insulating element on the first organic film and on the contacting areas;
f) forming openings in the electrically insulating-element so as to make the contacting areas accessible; and
g) forming conductive elements on the contacting areas.

2. The method according to claim 1, wherein depositing the electrically-insulating element comprises one of: laminating a second organic film or depositing a passivation layer.

3. The method according to claim 1, wherein the conductive elements are electrically-conductive pillars or solder balls.

4. The method according to claim 1, further comprising using laser ablation to form the openings in the first organic film and/or the openings in the electrically-insulating element are made.

5. The method according to claim 1, wherein the conductive elements are formed opposite the through vias.

6. The method according to claim 1, wherein the contacting areas of the conductive areas are continued on the upper surface of the first organic film, and wherein the conductive elements are offset with respect to the conductive areas.

7. The method according to claim 1, further comprising, prior to step d), a step of forming an electrically-insulating material on a second surface of the substrate and on lateral surfaces of the substrate.

8. A device, comprising:
a substrate having a first chip formed therein and having conductive pads positioned thereon;
a second chip mounted on a first surface of the substrate;
wherein a first surface of the second chip is arranged opposite the first chip and connected to the first chip;
wherein the second chip comprises through vias emerging onto a second surface of the second chip;
a first organic film laminated onto the first surface of the substrate and onto the second chip, the first organic film including openings located opposite the conductive pads and the through vias;
contacting areas extending from an upper surface of the first organic film, on one hand, all the way to the conductive areas and, on another hand, all the way to the through vias, the contacting areas of the conductive pads continuing on an upper surface of the first organic film;
an electrically-insulating element covering the first organic film, the electrically-insulating element having openings which make the contacting areas accessible; and
conductive elements on the contacting areas.

9. The device according to claim 8, wherein the electrically-insulating element comprises one of a second laminated organic film or a passivation layer

10. The device according to claim 8, wherein the conductive elements comprise one of solder balls or conductive pillars.

11. The device according to claim 8, further comprising an electrically-insulating material on a second surface and on lateral surfaces of the substrate.

12. The device according to claim 8, wherein the contacting areas of the conductive areas continue on the upper surface of the first organic film, and wherein the conductive elements are offset with respect to the conductive areas.

13. The device according to claim 8, wherein the conductive elements are located opposite the through vias.

14. The device according to claim 8, further comprising an electrically-insulating material on a second surface of the substrate and on lateral surfaces of the substrate.

15. An assembly, comprising:
the device according to claim 8, and
a printed circuit board comprising connection areas;
wherein the conductive elements are assembled on the connection areas using solder pads.

16. The method, comprising:
manufacturing the assembly of claim 15;
assembling the conductive elements on the connection areas of the printed circuit board using soldering.
